(19) United States
(12) Patent Application Publication
(10) Pub. No.: US 2026/0110554 A1
(43) Pub. Date: Apr. 23, 2026

(54) CIRCUITRY, CIRCUIT ASSEMBLY AND METHOD

(71) Applicant: Renesas Electronics America Inc., Milpitas, CA (US)

(72) Inventor: Kaloyan Diyanov DANAILOV, Varna (BG)

(73) Assignee: Renesas Electronics America Inc., Milpitas, CA (US)

(21) Appl. No.: 18/920,384

(22) Filed: Oct. 18, 2024

(51) Int. Cl. G01D 5/22

(52) U.S. Cl. CPC G01D 5/22

(57) ABSTRACT

Described herein is a circuitry for use with an inductive sensor. The inductive sensor comprises: a transmitter coil and two back-to-back connected receiver coils for receiving signals induced by a magnetic field generated by the transmitter coil when excited; and a movable conductive target for influencing the magnetic field. In particular, the circuitry is configured for generating a sequence of pulses for discontinuously exciting the transmitter coil.

### TECHNICAL FIELD

The present disclosure is generally directed to techniques related to contactless switches, and more particularly to techniques related to contactless switches based on inductive position sensing.

### BACKGROUND

Inductive position sensing (IPS) is a generally known technology utilized in various applications to measure the position or proximity of metallic objects. For example, traditional devices like inductive resolvers employ a set of inductive coils to determine the position of a metallic target placed in front of them. Similarly, Hall effect switches are commonly used to detect magnetic fields for position sensing purposes.

In a possible implementation of the conventional inductive proximity switch, the sensor typically comprises a transmitter (TX) coil and a receiver (RX) coil. The receiver coil is often designed with two symmetrical segments that have opposite orientations and are coupled or connected in series, as illustratively shown in FIG. 1 (which will be described in more detail below). An oscillator excites the resonant circuit formed by the transmitter coil and a parallel capacitor at its resonant frequency. Generally speaking, this configuration generates a high current in the transmitter coil while requiring a relatively low drive current.

However, conventional IPS based switch implementations may exhibit certain limitations. For instance, the LC tank, formed by the TX coil and the capacitor, would have a very low Q-factor (too many energy losses) and the performance requirements for the rest of the circuit would get drastically increased if the oscillation frequency goes up.

Therefore, there exists a need for an improved design for the IPS based contactless switch that can overcome some or all of the problems associated with conventional techniques, and more particularly, that enables miniaturization of the sensor coils (preferably to integrate them in the silicon die), i.e., to be able to work with extremely low inductance of the TX/RX coils.

### SUMMARY

In view of some or all of the above technical problems, the present disclosure generally provides a circuitry, a circuit assembly, and a corresponding method, having the features of the respective independent claims.

According to an aspect of the disclosure, there is provided a circuitry (sometimes also referred to herein as a circuit design, setup, implementation, assembly, or the like). Such circuitry (e.g., application-specific integrated circuit (ASIC), or the like) may be for use with an inductive sensor (e.g., an inductive position sensing (IPS) based sensor). The inductive sensor and the circuity may be suitably coupled together, for example for joint operation.

In particular, the inductive sensor may comprise a transmitter/transmitting (TX) coil and two back-to-back connected receiver/receiving (RX) coils. The two receiver coils may be, but do not necessarily have to be, identical. The receiver coils may be configured for receiving signals induced by a magnetic field generated by the transmitter coil when excited (e.g., by a trigger or excitation signal). The inductive sensor may further comprise a movable conductive target for influencing the magnetic field. For instance, the target may be made of any suitable metallic material, such as copper or the like.

More particularly, the circuitry may be configured for generating a sequence of pulses (pulse signals) for discontinuously exciting the transmitter coil. The pulse may be in any suitable shape, such as square, rectangular, or the like.

With this, the present disclosure generally proposes a circuitry (ASIC) design that enables miniaturization of the sensor coils (preferably to integrate them in the silicon die), i.e., to be able to work with extremely low inductance of the TX/RX coils. More particularly, considering short pulses as TX signal (e.g., ˜30 ns or the like), the efficiency of the transformer (sensor) could still be high enough even with much smaller inductances of the coils. Together with that, the energy efficiency gets drastically increased and the design of the TX driver is greatly simplified. Further, the glitch-like TX signal (e.g., short rectangular pulse) typically has a quite wide spectrum bandwidth, which generally increases the efficiency of the energy transfer between the TX and RX coils of the sensor transformer, even when the last is miniaturized and the coils' inductance is low. This holds true particularly thanks to the high frequency components in the TX signal.

Moreover, the power consumption of the sensor could be significantly reduced, as there would not be a continuous supply of current to the coils. In addition, there would also be no need for a rectifier as both the currents supplied to the coils and the currents induced are already in a form suitable for further processing. Finally, the pulse driving approach also enables implementation of randomized TX pulse phases, with several positive effects from for example electromagnetic compatibility (EMC) and noise perspective, which were not applicable to the conventional techniques. For instance, the EM radiation that the transmitting coil may create to neighbouring circuits may be reduced.

In some example embodiments, the generation of the sequence of pulses may involve a randomized clocking scheme, so that the generated sequence of pulses have a variable duration between two consecutive pulses. For instance, this may be achieved by use of an analog random generator, or by any other suitable means. Thereby, EMC disturbances that the TX coil may cause for neighboring circuits may be greatly reduced.

In some example embodiments, the circuitry may comprise a comparator stage configured for generating an output signal indicative of a position of the target relative to the receiver coils based on a differential output signal generated by the receiver coils. In some possible examples, the comparator stage may be implemented as simply as a conventional comparator. Of course, any other suitable implementation may be adopted as well, depending on various circumstances and/or requirements.

In some example embodiments, the comparator stage may comprise a compensation stage coupled to the receiver coils for applying an asymmetric attenuation or amplification to a differential output signal generated by the receiver coils.

In some example embodiments, the compensation stage may be configured for nulling (balancing) the differential output signal, so that a position of the target relative to the receiver coils can be inferred from information indicative of the applied attenuation or amplification. Thereby, a more precise position (with a certain resolution) of the target with respect to the receiver coils may be determined, compared to conventional techniques where it is usually only possible to determine whether the target is closer to one or the other of the two receiving coils. Nulling the differential output signal or balancing the P-channel and N-channel signals may be achieved by respective trim amplifiers or attenuators that are arranged in respective signal paths. For example, if the target is relatively closer to the N-channel coil (or has greater overlap with the N-channel coil), the N-channel signal will be smaller in magnitude that the P-channel signal. Then, the P-channel signal may require attenuation (or more attenuation) for nulling the differential output signal. Consequently, the fact that more attenuation is applied to the P-channel signal than to the N-channel signal may indicate that the target is relatively closer to (or has more overlap with) the N-channel coil, and vice versa.

In some example embodiments, the compensation stage may comprise two attenuators or amplifiers configured for individually attenuating or amplifying respective outputs of the receiving coils. Thereby, asymmetric attenuation or amplification of the differential output signal can be achieved.

In some example embodiments, the attenuators or amplifiers may have variable (e.g., adjustable) gains for generating an output signal indicative of a position of the target relative to the receiving coils.

In some example embodiments, the comparator stage may comprise a super regenerative receiver (SRR) concept-based stage that is capable of self-quenching, such that an output of the SRR concept-based stage is gradually recoverable to a safe state in case of fault. In other words, the output is enabled to be recoverable to a neutral state after a certain period of time if the input signal has disappeared due to some reason.

In some example embodiments, the circuitry may further comprise an integrator stage that is configured to be charged or discharged based on an output of the comparator stage. In some possible examples, the integrator stage may be implemented as simply as a (conventional) integrator. Of course, any other suitable implementation may be adopted as well, depending on various circumstances and/or requirements.

In some example embodiments, the circuitry may further comprise a control stage coupled to the integrator stage for controlling at least one integration constant (or coefficient, e.g., step, slop, or the like) indicative of how fast an output of the integrator stage changes for each consecutive integration cycle. In some possible examples, the control stage may comprise current sources configured to control the charging/discharging of the integrator stage. Of course, any other suitable implementation may be adopted as well, depending on various circumstances and/or requirements.

In some example embodiments, the control stage may be configured such that, when the output of the comparator stage indicates a change of the position, the output of the comparator stage gets integrated with a smaller step in the integrator stage, than the case when the output of the comparator stage that indicates no change of the position. This may be achieved, for instance, by carefully controlling the charging/discharging steps (or slopes) of the integrator, or by any other suitable means. Incidentally, it may be worth mentioning that one of the reasoning behind such asymmetrical integration may in fact be understood to deliver the so called probability hysteresis, which generally improves the plausibility of the switch triggering for example when operated in heavy noisy environment.

In some example embodiments, the circuitry may comprise both a compensation stage coupled to the receiving coils for attenuating or amplifying a differential output signal generated by the receiving coils, and a super regenerative receiver (SRR) concept-based stage coupled to the compensation stage that is capable of self-quenching. In some other possible examples, either one or even both of the compensation stage and the SRR concept based stage might be substituted with a comparator, for example to reduce cost and complexity.

In some example embodiments, the circuitry may be powered in synchronization with the sequence of pulses. Thereby, the power consumption of the overall system could be significantly reduced, as there would not be a continuous power supply.

In some example embodiments, the comparator stage may receive and process signals from the receiver coils synchronously with the sequence of pulses. Put differently in simple words, the whole signal path gets activated only during the TX pulses. For instance, in the case of a simple (conventional) comparator based implementation, the comparator may stay in the “reset” during the TX pauses and start the decision making process synchronously with the TX pulse generation. On the other hand, in the case when an SRR stage is used, it may also be driven in alignment with the TX pulse generation, thereby enabling the so-called “synchronous quenching”, because otherwise the SRR would be blocked for the RX signal due to natural noise. Moreover, the integrator stage may also be configured to perform a single integration step for every TX pulse, while during the pauses it stays in the “idle” state where the current integrated value is kept unchanged.

In some example embodiments, the circuitry may be configured for determining short or long distance, one-way or two-way movement of the target, and/or configured for sensing a linear position or a rotational angle of the target. Of course, as will be understood and appreciated by the skilled person, any other suitable operating mode and/or application scenario may be applicable as well, depending on various circumstances and/or requirements.

Correspondingly, according to another aspect of the present disclosure, there is also provided a circuit assembly that comprises both the circuitry according to the preceding aspect and the inductive sensor that are coupled in series.

Further, according to yet another aspect of the present disclosure, there is provided a method of operating a circuitry for use with an inductive sensor. The inductive sensor may be analogous or similar to that described above. For instance, the inductive sensor may comprise a transmitter coil and two back-to-back connected receiving coils for receiving signals induced by a magnetic field generated by the transmitter coil when excited. The inductive sensor may further comprise a movable conductive (e.g., copper) target for influencing the magnetic field.

In particular, the method may comprise generating a sequence of pulses for discontinuously exciting the transmitter coil.

Configured as proposed, broadly speaking, the present disclosure generally seeks to propose techniques that may enable miniaturization of the sensor coils (preferably to integrate them in the silicon die), i.e., to be able to work with extremely low inductance of the TX/RX coils. More particularly, considering short pulses as TX signal (e.g., ˜30 ns or the like), the efficiency of the transformer (sensor) could still be high enough even with much smaller inductances of the coils. Together with that, the energy efficiency gets drastically increased and the design of the TX driver is greatly simplified. Further, the glitch-like TX signal (e.g., short rectangular pulse) typically has a quite wide spectrum bandwidth, which generally increases the efficiency of the energy transfer between the TX and RX coils of the sensor transformer, even when the last is miniaturized and the coils'inductance is low. This is true particularly thanks to the high frequency components in the TX signal. Moreover, the power consumption of the sensor could be significantly reduced, as there would not be a continuous supply of current to the coils. In addition, there would also be no need for a rectifier as both the currents supplied to the coils and the currents induced are already in a form suitable for further processing. Finally, the pulse driving approach also enables implementation of randomized TX pulse phases, with several positive effects from for example electromagnetic compatibility (EMC) and noise perspective, which were not applicable to the conventional techniques. For instance, the EM radiation that the transmitting coil may create to neighbouring circuits may be reduced.

Details of the disclosed method may be implemented as systems (e.g., in the form of circuitry) adapted to execute some or all of the steps of the method, and vice versa, as the skilled person will appreciate. In particular, it is understood that methods according to the disclosure relate to methods of operating the systems (or circuitry) according to the above embodiments and variations thereof and that respective statements made with regard to the systems (or circuitry) likewise apply to the corresponding methods, and vice versa.

It is also understood that in the present disclosure, the term “couple” or “coupled” refers to elements being in electrical communication with each other, whether directly connected e.g., via wires or in some other manner (e.g., indirectly). Notably, one example of being coupled is being connected.

### BRIEF DESCRIPTION OF THE DRAWINGS

Example embodiments of the disclosure are explained below with reference to the accompanying drawings, wherein like reference numbers indicate like or similar elements, and wherein

FIG. 1 schematically illustrates an example of a possible implementation of a conventional inductive position sensing (IPS) based sensor,

FIG. 2 schematically illustrates an example of a possible conventional implementation comprising both the inductive sensor of FIG. 1 and an application-specific integrated circuit (ASIC) usable with the switch,

FIGS. 3A and 3B schematically illustrate examples of possible arrangements of the inductive sensor in relationship to the ASIC,

FIG. 4 schematically illustrates an example of a possible implementation of coils of the inductive sensor,

FIG. 5 schematically illustrates another example of a possible implementation of an inductive sensor,

FIG. 6 schematically illustrates an example of a possible output and behavior of the inductive sensor of FIG. 5,

FIG. 7 schematically illustrates an example of a possible implementation of a circuit assembly comprising both the TX part of the inductive sensor and the ASIC according to embodiments of the present disclosure,

FIG. 8 schematically illustrates another example of a possible implementation of a circuit assembly comprising both the inductive sensor and the ASIC according to embodiments of the present disclosure,

FIG. 9A and FIG. 9B schematically illustrate examples of a possible implementation of determining the digitized position of the target of the sensor according to embodiments of the present disclosure,

FIGS. 10A-10E schematically illustrate examples of possible implementations of application scenarios of the circuit assembly according to embodiments of the present disclosure, and

FIG. 11 is a flowchart schematically illustrating an example of a method of operating a circuitry for use with an inductive sensor according to embodiments of the present disclosure.

### DETAILED DESCRIPTION

As indicated above, identical or like reference numbers in the present disclosure may, unless indicated otherwise, indicate identical or like elements, such that repeated descriptions thereof may be omitted for reasons of conciseness. Moreover, it is also to be noted that the symbols used in the figures, unless indicated otherwise, are merely for illustrative purposes, and thus should not be understood to constitute a limitation of any kind.

As briefly mentioned above, broadly speaking, this present disclosure generally relates to the technical area of contactless switch, and more particularly to techniques related to contactless switch based on inductive position sensing (IPS) techniques.

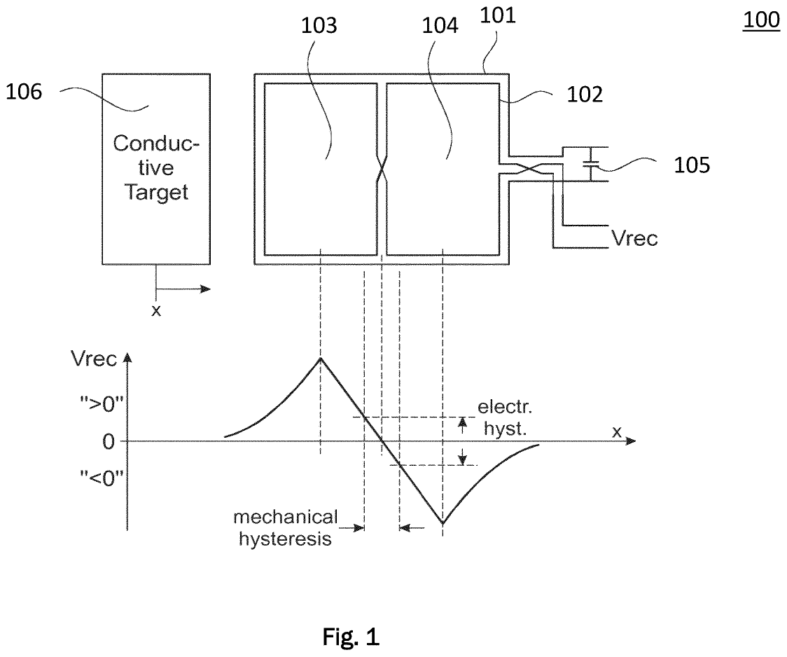

As illustratively shown for example in FIG. 1, a typical sensor implementation 100 may typically comprise a transmitter coil 101 and a receiver coil 102. The receiver coil 102 may often designed with two symmetrical segments 103 and 104 that have opposite orientations and are connected in series. An oscillator excites the resonant circuit formed by the transmitter coil 101 and a parallel capacitor 105 at its resonant frequency.

An alternating current (AC) in the transmitter coil 101 produces an alternating magnetic field, which in turn induces voltages in the receiver coil segments 103 and 104. Sometimes, these receiver coil segments may be seen or implemented as (separate) receiver coils. In the absence of a target 106, the induced voltages in the two symmetrical receiver coil segments 103 and 104 would be equal in magnitude but opposite in sign, thus summing up to zero voltage.

When a conductive target 106 approaches the sensor, eddy currents would be induced within the target material. These eddy currents generate a counteracting magnetic field that reduces the total magnetic flux in both the transmitter and receiver coils 101 and 102 underneath the target 106. Consequently, the induced voltage in the region of the receiver coil 102 closest to the target 106 is reduced. If the target 106 does not cover identical areas of the two receiver coil segments 103 and 104, a net voltage Vrec can be measured at the receiver coil terminals. The sign (polarity) of this voltage corresponds to the segment with lesser (smaller) target coverage, as illustratively depicted in the lower part of FIG. 1.

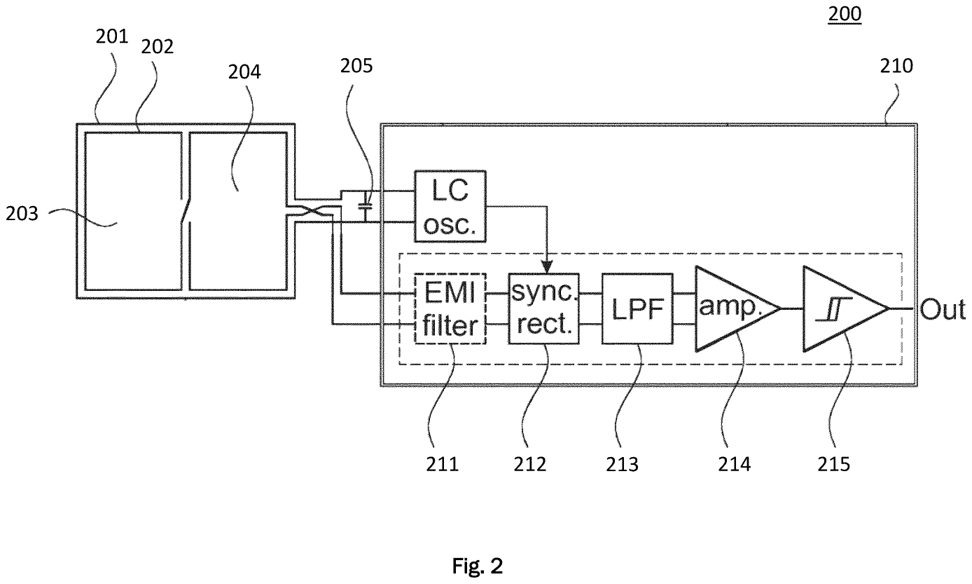

From the sign of the output voltage, it is possible to determine whether the target is overlapping more with segment 103 or segment 104 in FIG. 2. In a broad sense, this enables an implementation of 2-state (in the present case, left or right) switch/sensor.

In some possible implementations, the output voltage Vrec may be provided to an application-specific integrated circuit (ASIC) 210 as illustratively shown in FIG. 2. As indicated above, identical or like reference numbers in FIG. 2 indicate identical or like elements in FIG. 1, such that repeated descriptions thereof may be omitted for reasons of conciseness. Specifically, in the example of FIG. 2, the ASIC 210 schematically comprises an electromagnetic interference (EMI) filter 211, a rectifier 212, a low pass filter 213, an amplifier 214 and a comparator 245. Of course, this is merely one possible example for illustrative purposes, and should not be understood to constitute a limitation of any kind. As will be understood and appreciated by the skilled person, any other suitable design for the ASIC may be adopted as well, depending on various implementations and/or circumstances.

One of the main practical limitations for such conventional inductive sensor techniques may be understood to lie in the LC tank, formed by the TX coil and the capacitor, which might have a very low Q-factor (too much energy losses), and as a result, the performance requirements for the rest of the circuit would get drastically increased if the oscillation frequency goes up.

Therefore, in a broad term, one of the primary technical objectives of the present disclosure is finding a low power ASIC architecture, enabling miniaturization of the sensor coils (preferably to integrate them in the silicon die), i.e., to be able to work with extremely low inductance of the TX/RX coils. Any other applicable objective and/or advantages of the present disclosure would also become apparent in view of the detailed description below.

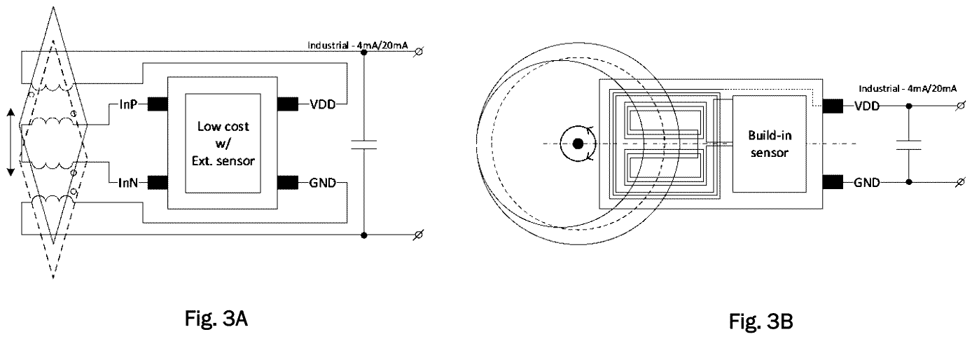

As mentioned above, the present disclosure generally relates to an ASIC that is capable of processing the differential output of an induction-based sensor coupled to its input. Depending on various implementations, the sensor may be separate to the ASIC (as illustratively shown in FIG. 3A), or integrated (as illustratively shown in FIG. 3B).

Concerning the sensor part, a simple implementation example has already been illustratively described above with reference to FIG. 1.

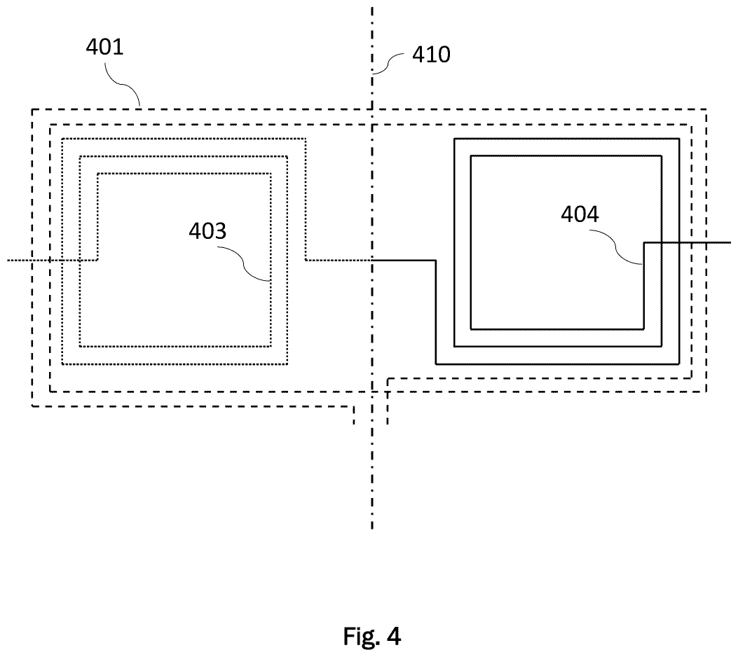

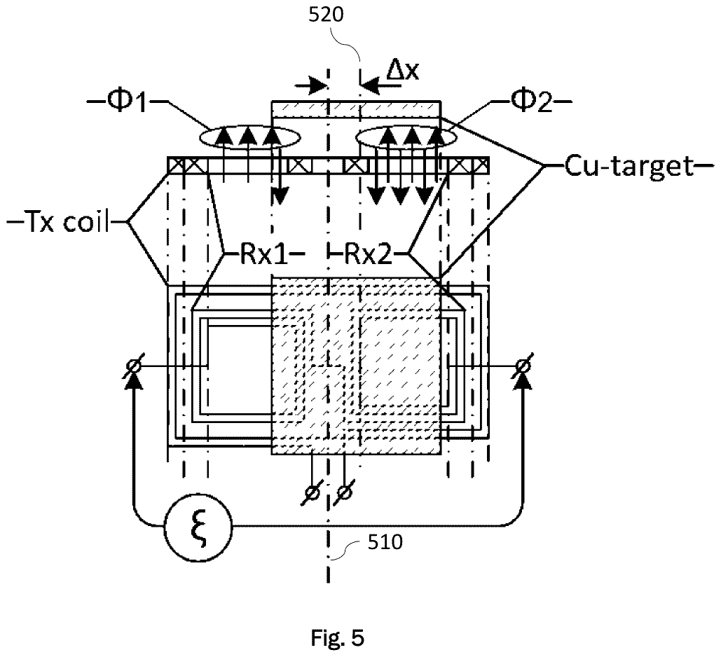

Now, reference is made to FIG. 4, which schematically illustrates possible arrangements of the coils of the senor. Another example (with a conductive target included therein), from two different perspectives (cross-sectional view in the upper part and top view in the lower part), is also illustratively shown in FIG. 5. Similar to above, identical or like reference numbers in FIG. 4 or FIG. 5, unless indicated otherwise, may be considered to indicate identical or like elements in FIG. 1, such that repeated descriptions thereof may be omitted for reasons of conciseness.

Particularly, as shown in FIG. 4, the dashed line 401 (“transmitting coil 401 ”) indicates the transmitting coil (denoted as “Tx coil” in FIG. 5), the dotted line 403 (“Rx1 403”) indicates the first receiving coil (denoted as “Rx1” in FIG. 5) and the solid line 404 (“Rx2 404”) indicates the second receiving coil (denoted as “Rx2” in FIG. 5). The line comprising both dots and dashes 410, 510 is used to illustratively indicate the axis of symmetry for the Rx1 and Rx2.

As can be observed from FIGS. 4 and 5, the transmitting coil 401 fully surrounds the two receiving coils 403 and 404. As Rx1 403 and Rx2 404 are identical and symmetrically positioned, in the absence of any other elements (such as a conductive element), the magnetic flux generated by transmitting coil 401 that permeates Rx1 403 is equal to the magnetic flux that permeates Rx2 404. In such conditions, the induced current in Rx1 and Rx2 would completely cancel each other.

The sensor further may comprise a conductive element (denoted as “Cu-target” in FIG. 5). In a possible implementation, the conductive element may be a solid copper plate. The conductive element may take various shapes. In a possible implementation, the conductive element may be shaped to be symmetrical, with a symmetry axis 520 that is parallel to the symmetry axis indicated by dashes 510 of Rx1 and Rx2.

When the sensor is in use, the conductive element is positioned such that it faces the two receiving coils, Rx1 and Rx2. The conductive element is also permeated by the field generated by the transmitting coil Tx. The AC field component induces Eddy currents on the conductive plate, which leads to reduction of the total magnetic flux in the covered areas.

When the target symmetry axis 520 does not match the coils'one 510 (Δx), an asymmetry in the flux distribution would be created, resulting in non-zero electromotive force (ξ) in the receiving part (Rx1+Rx2). In other words, the described system may be considered to behave as a known differential transformer. Generally speaking, the value of the induced signal (ξ) depends on the displacement (Δx), but also on the target size and shape which could be used for adjustment of the switch mechanical threshold and hysteresis.

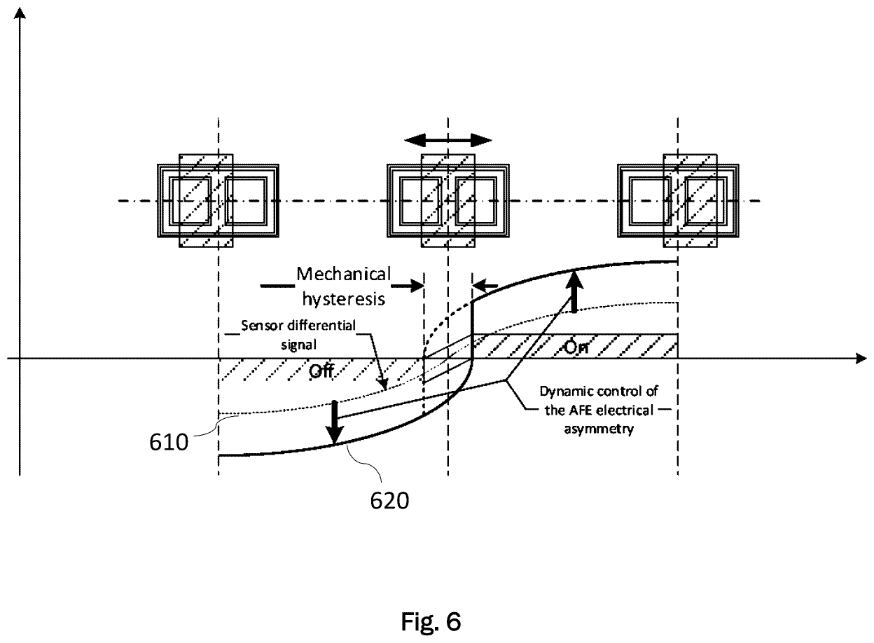

Therefore, from the polarity of the induced signal (ξ), it is possible to determine whether the conductive element, i.e., the CU-target is presently in a position closer to Rx1 or closer to Rx2. An illustrative diagram showcasing the possible output and behaviour of the sensor is given in FIG. 6. Therein, the dotted line 610 (marked as “sensor differential signal”) generally represents the differential output of the sensor as the CU-target moves over the receiving coils Rx1 and Rx2. The thick line 620 generally represents the output of the ASIC, as will be explained in more detail below.

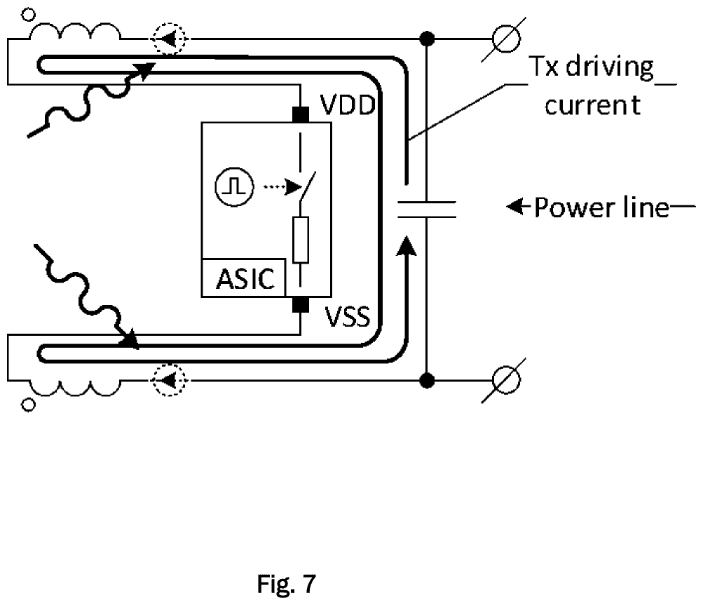

Now, turning to the ASIC part, which is generally considered one of the main aspects of the present disclosure, firstly, in order to keep the pin-count of the end product as low as possible, the transmitting coil may be coupled (connected) in series with an ASIC supply (as also illustratively shown in FIGS. 3A and 3B) and is stimulated by a sequence of (short) pulses as indicated in FIG. 7. Incidentally, it is to be noted that, for the sake of brevity, FIG. 7 only illustratively shows the TX part of the sensor, but not the RX coils nor the connections, as can also be understood and appreciated by the skilled person. In some possible implementations, the pluses may be implemented as a sequence of square (or rectangular) pulses. Of course, any other suitable pulse implementation may adopted as well, as will be understood and appreciated by the skilled person. This is a first major difference compared to conventional techniques, wherein, as illustrated above, the coils are typically supplied by AC currents.

To be more specific, whilst in conventional sensor implementations (such as those shown in FIGS. 1 and 2) the coils are provided with an AC current from an oscillator, in the present disclosure the ASIC may provide (e.g., square) pulses to the transmitter coil to discontinuously excite the transmitter coil. Notably, exciting the transmitter coil with short (discontinuous) pulses may be considered to have at least the following effects.

First, a glitch-like TX signal (e.g., short rectangular pulse) typically has a quite wide spectrum bandwidth. This may increase the efficiency of the energy transfer between the TX and RX coils of the sensor transformer, even when the last is miniaturized and the coils' inductance is low. This holds true particularly due to the high frequency components in the TX signal.

Further, the power consumption of the sensor can be significantly reduced, as there would not be a continuous supply of current to the coils necessary, in comparison to the AC current based conventional techniques. Accordingly, the ASIC may also be powered in synchronization with the sequence of pulses.

Moreover, there would also be no need for a rectifier as both the currents supplied to the coils and the currents induced are already in a form suitable for further processing.

Yet, the electromagnetic (EM) radiation that the transmitting coil may create to neighbouring circuits could also be reduced.

And finally, the design of the TX excitation generator can be greatly simplified as well.

In some possible implementations, the clocking scheme for the generation of the pulses may be randomized (e.g., by use of an analog random generator). Thereby, the electromagnetic compatibility (EMC) disturbances that the TX coil may cause for neighboring circuits may be greatly reduced. In other words, the use of the randomized clock scheme may break any possible correlation with for example external disturbance signals, thereby bringing a positive effect for increasing immunity against electromagnetic disturbances.

In some further possible cases, the transmitting coil may considered to behave as an antenna when exposed to an external EM field. In such cases, in some possible implementations, for better system EMC performance, the transmitting coil might be split into two identical halves and connected back-to-back (similar to the receiver coil segments).

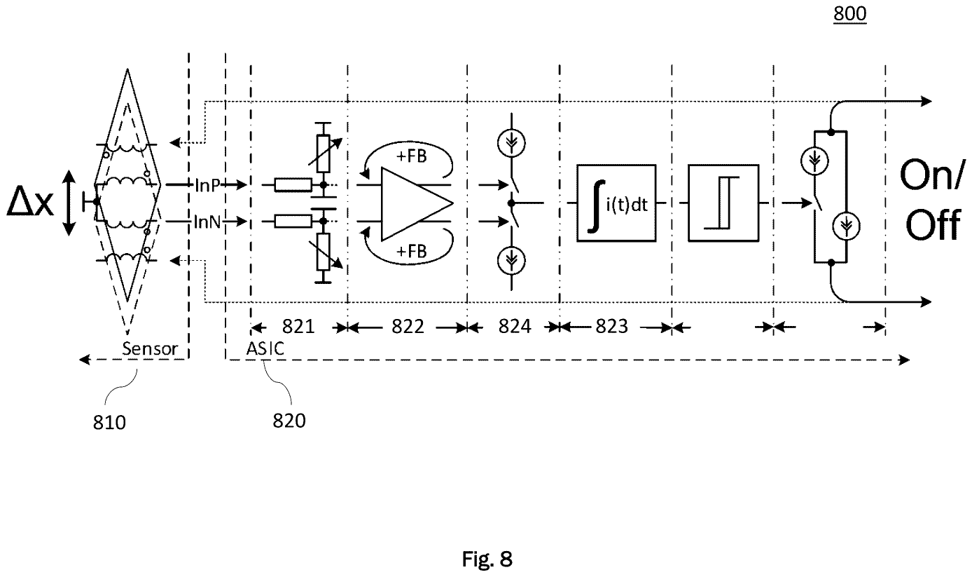

Reference is now made to FIG. 8, which schematically illustrates a possible circuity implementation of the ASIC 820 according to embodiments of the present disclosure. The ASIC 820 is coupled to and usable together with the inductive sensor 810.

Particularly, upon receipt of the differential output signal (denoted as “InP” and “InN” in FIG. 8) from the sensor 810, a first stage in the receiving path may be referred to as a compensation stage (or sometimes also referred to as an attenuator stage, or the like) 821. Specifically, the compensation stage may be configured to apply an asymmetric attenuation (or amplification) to the differential output signal generated by the receiver coils.

In some possible examples, this compensation stage may be implemented as simply as comprising attenuators. It may be worth noting that, as will also become apparent in view of the description below, although the term “attenuator” is used herein, such attenuators (or more generally, the compensation/attenuator stage) are capable of providing a gain that is not only less than 1 (unity gain), but also larger than (or sometimes also equal to) 1. In that sense, it may be understood that the “attenuator” may in some cases also behave like an amplifier. Similarly, it may also be possible to implement this compensation stage by using amplifiers (or a combination of amplifier(s) and attenuator(s)) that are also capable of providing a gain that is less than 1. Of course, any other suitable implementation may be adopted as well, as will be understood and appreciated by the skilled person.

In some possible implementations, the relative position of the target may be used to define the asymmetric attenuation (or amplification) of the signals in both receiver coils. That is to say, if the target is closer to Rx1, the flux on Rx1 may be attenuated more than the flux permeating Rx2, which would then result in the non-zero differential output of the sensor.

The use of the compensation stage (which may be implemented as attenuators and/or amplifiers, as illustrated above) at the input stage may produce at least the following technical effect(s).

By being able to individually and differently attenuate/amplify the output of each coil, it may be possible to move the crossover boundary at which point the switch/sensor changes state (ON/OFF, left/right, or the like). In other words, one effect of the attenuators is the possibility to (artificially/virtually) “move” the switch threshold point mechanically across the sensor active area, which in turn enables insertion of mechanical hysteresis of the system. Notably, this effect is also illustratively shown and marked as “Dynamic control of the AFE electrical asymmetry” in the figures.

Furthermore, in some possible examples, the attenuators/amplifiers may be implemented to have variable gains. In such cases, it may also be possible to determine the actual location of the target (with higher resolution), instead of just estimating whether the target is closer to one or the other of the two receiving coils.

To be more specific, in some possible implementations, this asymmetric attenuation of the signals in both receiver coils, may be compensated or increased by the respective attenuators (or amplifiers). Once the respective attenuator/amplifier gain that compensates for the asymmetric attenuation is determined, it is then possible to determine from that the exact (at least to some extent) position of the target with reference to the receiving coils. Put differently, the compensation stage may be configured for nulling (balancing) the differential output signal (e.g., by using suitable trim amplifier(s) (or attenuators) together with any suitable search algorithm/strategy), so that a position of the target relative to the receiving coils can be inferred from information indicative of the applied attenuation or amplification.

An illustrative non-limiting example of inferring the target's position relative to the receiver coils may be as follows. If the system (i.e., compensation stage) needs to apply more attenuation to the P-channel than the N-channel of the differential output signal for balancing these signals (i.e., for nulling the differential output signal), it may be concluded that the target is relatively closer to the N-channel coil. The rationale is that the target being relatively closer to the N-channel coil implies a smaller N-channel signal, with then requires that the P-channel signal is attenuated relative to the N-channel signal for nulling the differential output signal. On the other hand, if more attenuation needs to be applied to the N-channel signal, it may be concluded that the target is relatively closer to the P-channel coil. As will be appreciated by the skilled person, attenuation factors for balancing the P-channel and N-channel signals that may be applied by suitable amplifiers may be found by a variety of search strategies or algorithms, such as successive approximation algorithms or the like, as will discussed in detail later. Importantly however, the skilled person will appreciate that suitable attenuation factors for balancing the P-channel and N-channel signals may be found, and that these attenuation factors allow inferring the target's position relative to the P-channel and N-channel coils. It is also understood that the aforementioned attenuation factors (or analogously, gain factors) may be relative to reference attenuation factors (or gain factors) that null the differential output signal for a symmetric arrangement of the target.

In some possible implementations, finding the right settings for the compensation stage may involve application of a suitable search algorithm. For instance, in some examples, a successive approximation algorithm may be implemented with hardware (HW) control logic, or software (SW) in the microcontroller unit (MCU), which may be configured to monitor the output of the switch/sensor for toggling at each iteration step. Of course, as will be understood and appreciated by the skilled person, any other suitable algorithms may be used as well, depending on various implementations and/or circumstances.

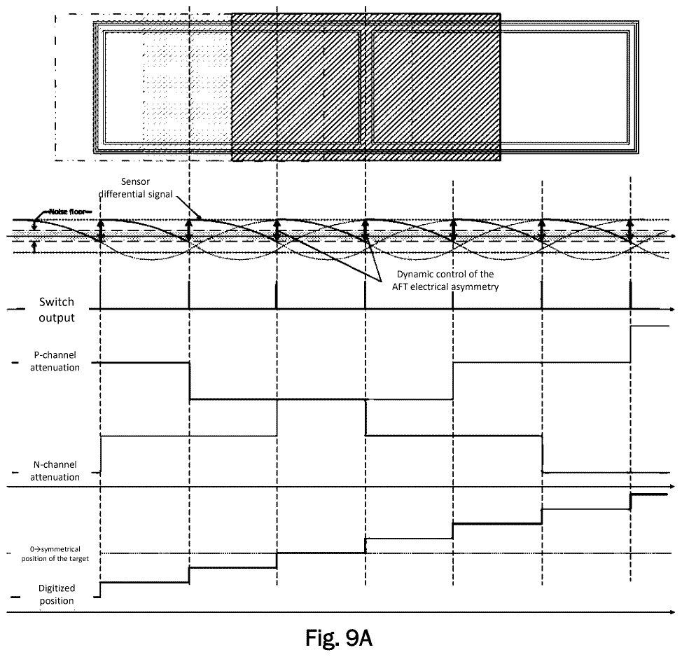

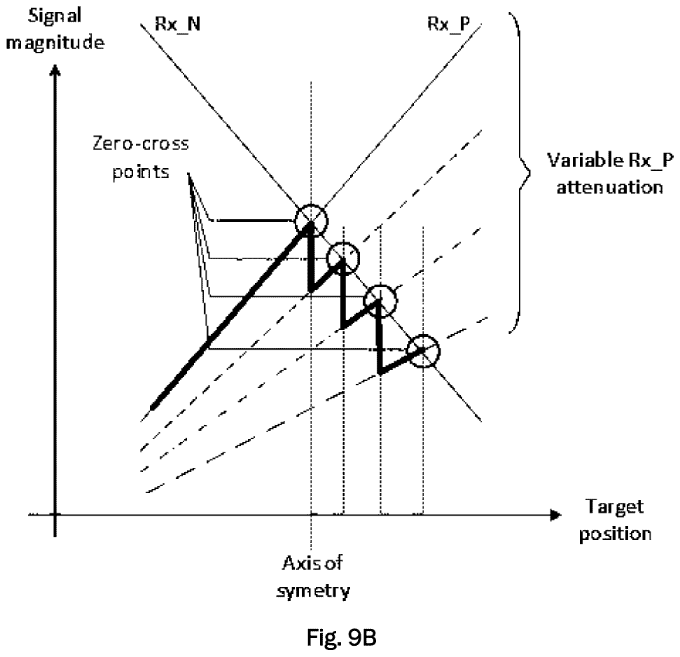

The output value from the search routine may in fact be viewed as a digitized representation of the target's relative position with respect to the sensor axis of symmetry. Illustrative examples are shown in FIG. 9A and FIG. 9B which schematically illustrate how determining the P-channel attenuation and the N-channel attenuation at the input stage of the ASIC of FIG. 8 may be used to determine the digitized position of the target.

In other words, the relative position of the target will influence relative signal strengths of the signals from the receiver coils (i.e., P-channel and N-channel signals), and hence will influence the attenuation factors (attenuation values) needed for balancing the signals from the receiver coils. Depending on the target position, the required attenuation factors are in general asymmetric, i.e., different for P-channel and N-channel signals. As the target moves along the receiver coils, the (asymmetric) attenuation factors may be dynamically adjusted using front-end compensation settings (e.g., with the help of trim amplifiers, or the like). This adjustment may be achieved by an appropriate search algorithm or strategy for the attenuation factors. The search algorithm (e.g., a successive approximation algorithm) may be used to determine the correct asymmetry compensation settings for each position, for example by checking the switch output (indicated by “Sensor differential signal” in FIG. 9A) and adjusting the respective attenuation settings (indicated by “P-channel attenuation” and “N-channel attenuation” respectively in FIG. 9A) iteratively, for example until the switch toggles, indicating that the required attenuation setting has been found (and by extension, the current position of the target has been detected). This is illustratively shown in the “Switch output” diagram of FIG. 9A. The asymmetric attenuation (P-channel attenuation and N-channel attenuation) values may be adjusted (e.g., iteratively) to balance the differential output signal detected by the receiver coils, until the differential output signal reaches or crosses a predetermined threshold, such as the “Noise floor” level as illustratively shown in FIG. 9A. As the target moves, whenever toggling of the switch output indicates that an adjustment of the attenuation factors is necessary, the present attenuation factors may be used as starting point for the search algorithm, so that for continuous linear motion of the target, the attenuation factor for one of the channels is gradually decreased (e.g., P-channel attenuation in FIG. 9A), while the attenuation factor for the other one of the channels is gradually increased (e.g., N-channel attenuation in FIG. 9A). A similar example is illustrated in the diagram of FIG. 9B, where new combinations of P-channel and N-channel attenuation values are determined at every zero crossing point of the differential output signal as the target moves from the P-channel coil towards the N-channel coil. Specifically, in this example the N-channel attenuation value is kept constant, while at every zero crossing point of the differential output signal (i.e., when the P-channel signal reaches the N-channel signal), the P-channel attenuation value is adjusted (i.e., increased) by a certain amount, as indicated by decreasing slopes of signals Rx_P.

The “Digitized position”, as also illustratively shown in the example of FIG. 9A, may be derived based on the difference between the P-channel and N-channel attenuation values and may be representative of the target position relative to the symmetrical axis of the sensor system. In the foregoing, granularity of available attenuation values will determine the granularity of the digitized position of the target.

It may be worth noting that this approach is applicable for both types of displacement of the target, namely linear or angular (when the accuracy requirements are not too high), and is particularly beneficial for its energy and cost efficiency. Generally speaking, the resolution of the measurement may be considered to be limited by the resolution of the asymmetry compensation attenuators/amplifiers.

It is also to be noted that the introduction of the compensation stage is indeed a major improvement over the conventional sensor techniques which may only indicate whether the target is closer to one or the other receiving coil (in other words, a 2-state switch). Particularly, introducing the compensation stage as proposed in the present disclosure generally allows determining exactly how much the target is closer to one or the other coil (thus resulting in a multi-state switch, or in other words a position sensor).

Further, returning to FIG. 8, a second stage 822 of the receiving path is implemented based on a modified super regenerative receiver (SRR) concept. The SRR concept per se may be considered to be generally well known to the person skilled in the field. In fact, in some possible cases, it may also be considered not mandatory for the function of the overall system that this stage is implemented as an SRR. For instance, in some possible examples, it could also be implemented as simply as a (conventional) comparator, where if the differential output is positive (for example in the case where the current generated at Rx1 is greater than the current generated at Rx2) the output of the stage would almost immediately become high (positive) potential (e.g., Vdd), whilst otherwise it would become low (negative) potential (e.g., Vss). In such cases, the switch would still function in general. However, as may be understood and appreciated by the skilled person, the output would be stuck to the positive or negative voltage rail of the comparator. This would lack an advantageous feature offered by the SRR concept, that is, the ability to return to a safe state in case of fault.

In a broad sense, this SRR concept based stage relies on positive feedback from its output, which is fed to an LC oscillator coupled to its input that amplifies the input signal until it reaches the magnitude of the supply voltage. In that sense, the output may be similar to that of a comparator, however, with SRR this value would be reached gradually (until it is saturated). For the SRR to function as intended, the supply current that excites the transmitting coil would be in pulses, as illustrated above.

In addition, in some possible implementations, there may also be an integrator stage 823 that follows the SRR stage 822 and could be charged or discharged appropriately (for example via the current sources of control stage 824, or the like) based on the output of the SRR 822. That is, the integrator stage 823 may be configured to perform an integration of the multiple decisions taken by the comparator later. In this sense, the integrator stage 823 may be understood to be able to filter out the noise and make the right decision whether the target has been placed on the position (e.g., for on-state or off-state) if it accumulates a certain amount of right decisions that the comparator delivers. In some possible examples, this integrator stage 823 may be configured such that it is capable of performing integration in both directions. That is to say, it is not simply counting a certain number of positive output signals from the comparator, but it is also able to subtract out of the accumulated value in case of a wrong decision (for example due to noise impact, or external disturbance, or the like). And the rate (step/slop) at which it increases or decreases its output may be different in some possible implementations, which in turn ensures a certain hysteresis in the system, thereby enabling a certain level of noise immunity.

In some possible cases, the current sources of the control stage 824 may be configured to suitably control the magnitude of the output of the integrator stage 823 and in practice produce an electrical hysteresis effect on the switch/sensor. That is to say, in some possible examples, the control stage 824 may be coupled to the integrator stage and configured for controlling at least one integration constant (or coefficient/parameter, e.g., step, slope, or the like) indicative of how fast an output of the integrator stage changes for each consecutive integration cycle (when its input (e.g., the comparator or SRR output) gets changed). Furthermore, in some possible examples, the control stage 824 may be configured such that, when the output of the SRR stage 822 (or in the case of a simple comparator based implementation, the output of this comparator) indicates a change of the position of the target, the output gets integrated with a smaller step (slop) in the integrator stage 823, than the case when the output of the SRR or of the comparator indicates no change of the position. It may be worth mentioning that, one of the reasoning behind such asymmetrical integration may in fact be understood to deliver the so called probability hysteresis, which generally improves the plausibility of the switch triggering for example when operated in heavy noisy environment. Of course, as can be understood and appreciated by the skilled person, the control stage 824 implemented by using current sources is merely provided as a possible example for illustrative purposes, and should not be understood to constitute a limitation of any kind. Depending on various circumstances, any other suitable implementation for the control stage 824 may be adopted as well. Notably, by passing the output of the SRR stage 822 to the integrator stage 823, the EMC robustness of the signal could be improved and any noise that may be present could be reduced. It further improves the stability of the switch output as it provides hysteresis to the output.

Unlike in a simple comparator based implementation, the SRR stage 822 may, particularly in case of fault, benefit from a so-called self-quenching action, which generally ensures that the output of this stage 822 would gradually recover to a safe state. In other words, the output is enabled to be recoverable to a neutral state after a certain period of time if the input signal has disappeared due to some reason. This in turn enables the switch/sensor to be appropriate for example for higher automotive safety integrity levels (ASILs) defined by ISO26262.

A major difference between a simple comparator-based implementation and the SRR concept-based technique proposed herein is the presence of an additional state (which may sometimes also be considered or referred to as a “safe state”) at the output of the SRR stage, to which it settles after a certain period of time in case of fault, such as a missing clock signal or the like. While the latched comparator would keep at its output the latest result from the decision-making process (e.g., “1” or “0”), the SRR stage generally does not stay in this state for long, and neither a “1”, nor “0” signal would reach the integrator stage. As a result, in case of fault the comparator-based switch may trigger wrongly, because it is generally not possible to guarantee that the latest latch results at its output would reflect the actual position of the target (e.g., due to noise impact or EM disturbance, etc.). On the contrary, the SRR concept-based IPS-switch would keep the latest valid state, simply because the mentioned additional safe state of the SRR stage output may be used for completely disabling of the charge/discharge current sources in the integrator stage. Furthermore, depending on application needs, the integrator stage might be built in a way to slowly discharge itself when such event occurs, which would ensure a predefined safe state of the switch (e.g., “On”, “Off”, or the like) to which the switch would automatically go independently of the target position and the latest valid state of the switch before the fault occurs. Thereby, the SRR concept-based technique as proposed herein has a clear advantage in comparison with a comparator, at least in terms of safety.

As noted above, the ASIC 820 may be powered in synchronization with the sequence of pulses in some cases, thereby bringing certain advantages from a power consumption point of view. In addition, in some possible implementations, the whole signal path may get activated only during the TX pulses. For instance, in the case of a simple (conventional) comparator based implementation, the comparator may stay in the “reset” during the TX pauses and start the decision making process synchronously with the TX pulse generation. On the other hand, in the case when an SRR stage 822 is used, it may also be driven in alignment with the TX pulse generation, thereby enabling the so-called “synchronous quenching”, because otherwise the SRR would be blocked for the RX signal due to natural noise. Moreover, the integrator stage 823 may also be configured to perform a single integration step for every TX pulse, while during the pauses it stays in the “idle” state where the current integrated value is kept unchanged.

It may be still worth mentioning that, in some possible examples, either one or even both of the above two stages, namely the compensation stage 821 and the SRR concept based stage 822, might be substituted with a single comparator, for example to reduce cost and complexity. In such cases, the control stage may be configured to ensure that, for a determined position, an output of the comparator that indicates a change of the position has a smaller output magnitude than that of an output of the comparator stage that indicates no change of the position. This may be achieved, for instance, by carefully controlling the charging/discharging slopes of the integrator, or by any other suitable means.

The rest of the circuity follows known receiving path topologies, and thus will not be discussed in detail for the sake of conciseness.

Nevertheless, it may be still worth noting that, even though the basic sensor configuration and principle might have been largely reused here, there still exist some important aspects for its design when intended to be used in the pulse driving system as proposed in the present disclosure. For example, the parasitic capacitance may be minimized. Further, contrary to conventional techniques, here the Q-factor of all resonances may be kept low enough, which usually requires insertion of additional resistive losses in the circuity. But it would also be possible to utilize the intrinsic resistance of the copper material for the coils on the sensor printed circuit board (PCB). To avoid the so-called “long wire” effect in the circuity, the total length of the wires forming the coils may be shorter (e.g., >10 times shorter) than the frequency components of the TX signal that are of interest for the switch operation, which may be defined by the cut-off frequency of the low pass filter in the circuitry. Moreover, for better performance of the proposed switch architecture, the sensor parameters may also need to be tuned to ensure aperiodic transition processes around the TX pulse edges, without significant ringing of the signals.

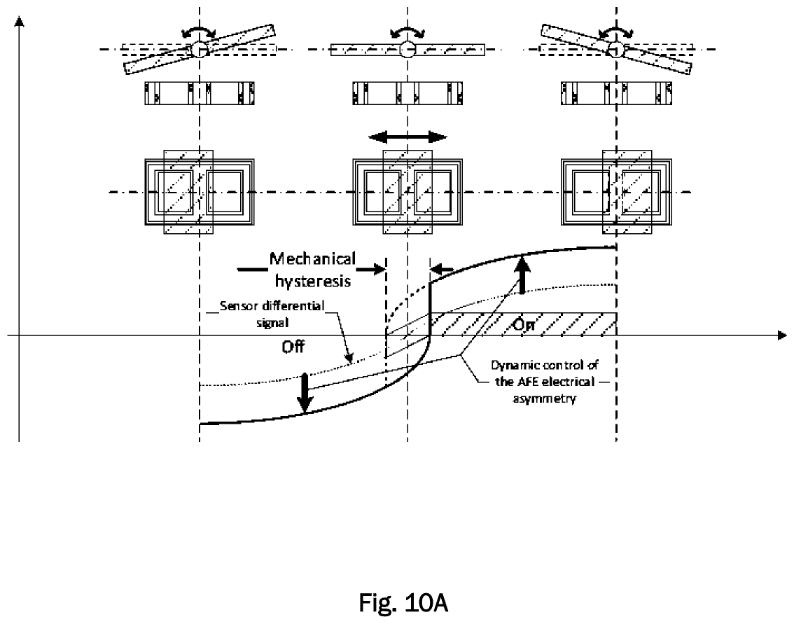

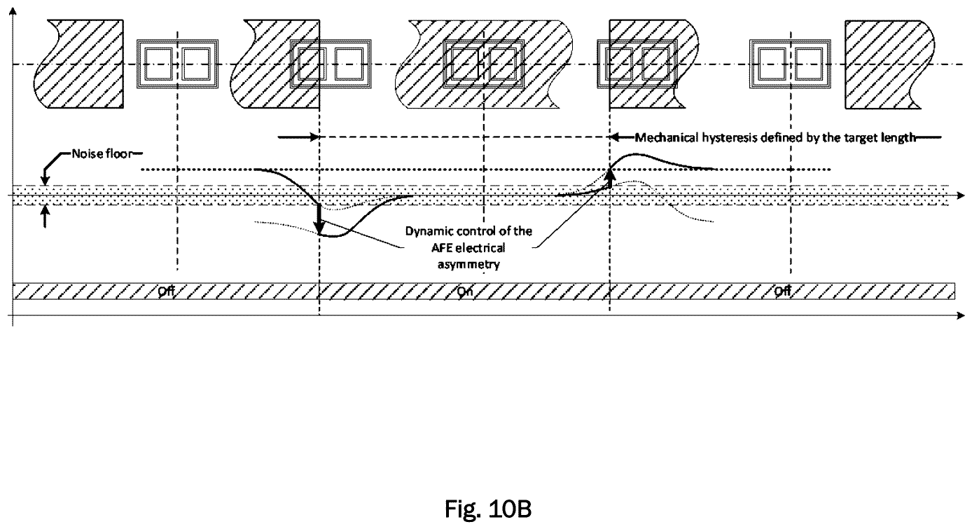

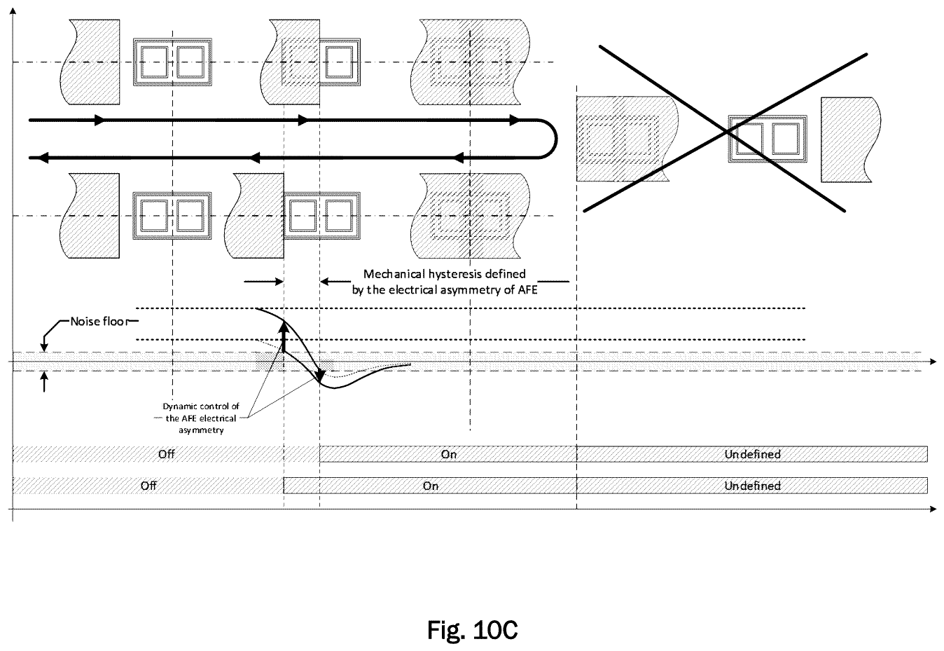

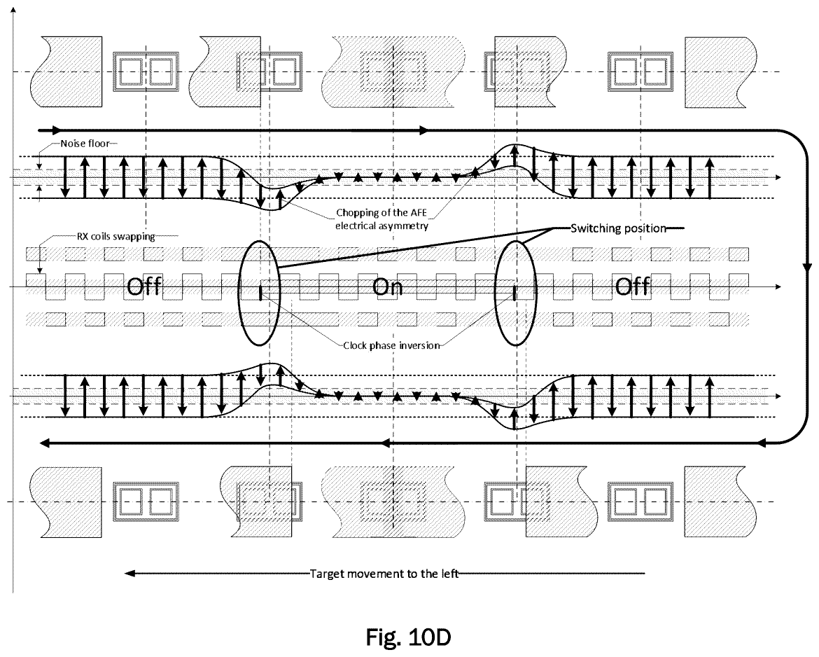

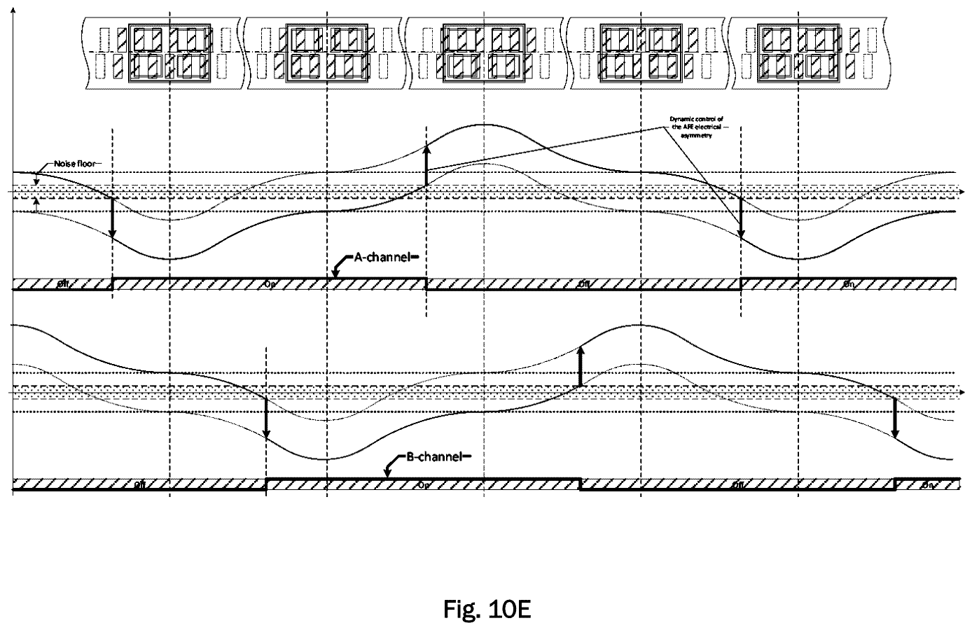

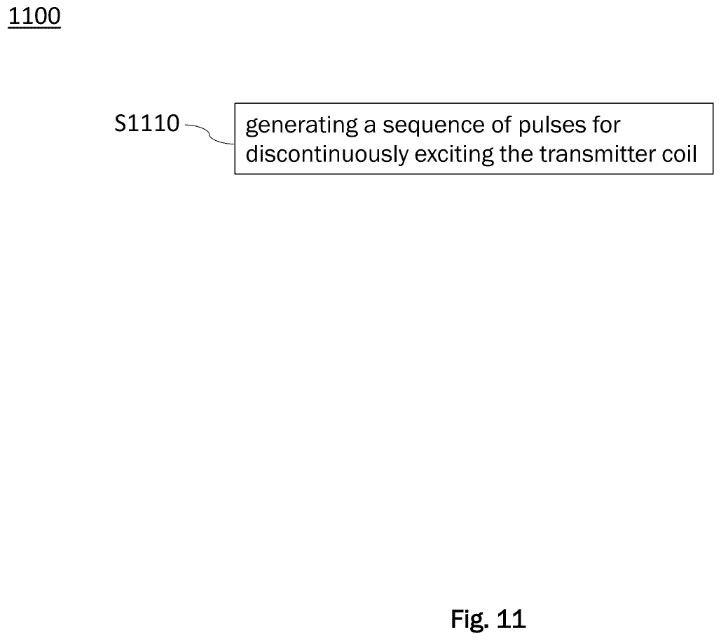

By utilizing techniques proposed in the present disclosure, the system may be applicable to various operating modes and application scenarios, some of which are illustratively shown in FIGS. 10A to 10E. In short, the proposed techniques are not only applicable to linear inductive position sensors as shown in FIG. 1, but to a wide variety of target and coil configurations, of which few non-limiting illustrative examples will be briefly described next.

In particular, FIG. 10A schematically illustrates an application scenario for detecting a short distance two-way (linear or angular) movement of the target. More particularly, in this case, the target is smaller than sensor coils and never leaves their active area. The state of the switch at power-up is fully defined. Specifically, this can be used for detection of any kind of local movement, when the mechanical displacement is smaller than the sensor dimensions.

FIG. 10B schematically illustrates an application scenario for detecting a long distance one-way movement of the target. More particularly, in this case, the target is larger than the sensor coils and may cover and leave the active area completely. The switching occurs when any of the target edges pass through the sensor active area. At the switching points the front-end asymmetry setting is reversed, enabling recognition of the front/back edge of the target. Accurate response could be obtained after a single initialization cycle after power-up (target-in and-out). Specifically, this may be considered suitable for industrial production lines or unidirectional large object movement detection.

FIG. 10C schematically illustrates an application scenario for detecting a long-distance two-way movement of the target, without passing the sensor. More particularly, in this case, the target is larger than the sensor coils and may cover and leave the active area completely. The switching occurs when the front edge of the target passes through the sensor active area. Unlike the previous case in FIG. 10B, the proper operation requires adding a static asymmetry to the front-end signal path, around which the settings toggle at the switching point, but do not change its sign, i.e., the signal from one of the receiver coils is always more attenuated than the other.

Accurate response is obtained after a single initialization cycle after power-up (target-in and -out). Specifically, this may be considered well suited for all kinds of end-point switches that are widely used in industrial installations.

FIG. 10D schematically illustrates an application scenario for detecting a long distance two-way movement of the target, surpassing the sensor. This may be considered as an enchantment of operating mode in FIG. 10B, eliminating the restriction for unidirectional movement. More particularly, in this case, the switching occurs when any of the target edges pass through the sensor active area in any direction. The front-end asymmetry settings toggle continuously, reconciling simultaneous operation of two sensors of the type of FIG. 10B, that work for movements in opposite directions. At the switching points the toggling phase gets reversed, which virtually swaps both sensors and prevents undefined state of the switch. Accurate response is obtained after a single initialization cycle at power-up (target-in and-out). Specifically, this mode of operation emulates the so-called “presence detection”, but still ensures stable and accurate switching positions compared to conventional techniques.

Finally, FIG. 10E schematically illustrates an application scenario of an incremental application binary interface (ABI) encoder, with a multi-stripe target. More particularly, there may be two possible realizations of such a system, which may use two copies of the sensor of coils of the previous embodiments but a multi-stripe target:
aligned pairs of receiver coils, combined with two rows of stripes in the target that are shifted between each other with a quarter period (illustrated above); or
a single raw multi-stripe target in combination with shifted pairs of receiver coils, again at quarter period.

The denser the stripes are the higher resolution of the displacement detection could be obtained, but the sensitivity of the system might be worsened. Accurate response is in place immediately after power-up, i.e., no need for initialization cycles

As indicated above, the above are merely listed as possible examples of application scenarios for illustrative purposes. As will be understood and appreciated by the skilled person, any other suitable operating mode and/or application scenario may be applicable as well, depending on various circumstances and/or requirements.

Finally, a flowchart illustrating an example of a method 1100 of operating a circuitry for use with an inductive sensor is schematically shown in FIG. 11. The circuitry as well as the inductive sensor may be implemented in accordance with the possible embodiment as described above with respect to the figures, or the like. For instance, the inductive sensor may comprise a transmitter coil and two back-to-back connected receiving coils for receiving signals induced by a magnetic field generated by the transmitter coil when excited. The inductive sensor may further comprise a movable conductive (e.g., copper) target for influencing the magnetic field.

In particular, method 1100 may comprise, at step S1110, generating a sequence of pulses for discontinuously exciting the transmitter coil.

Configured as proposed, broadly speaking, the present disclosure generally seeks to propose techniques that may enable miniaturization of the sensor coils (preferably to integrate them in the silicon die), i.e., to be able to work with extremely low inductance of the TX/RX coils. More particularly, considering short pulses as TX signal (e.g., ˜30 ns or the like), the efficiency of the transformer (sensor) could still be high enough even with much smaller inductances of the coils. Together with that, the energy efficiency gets drastically increased and the design of the TX driver is greatly simplified. Further, the glitch-like TX signal (e.g., short rectangular pulse) typically has a quite wide spectrum bandwidth, which generally increases the efficiency of the energy transfer between the TX and RX coils of the sensor transformer, even when the last is miniaturized and the coils'inductance is low. This is true particularly thanks to the high frequency components in the TX signal. Moreover, the power consumption of the sensor could be significantly reduced, as there would not be a continuous supply of current to the coils. In addition, there would also be no need for a rectifier as both the currents supplied to the coils and the currents induced are already in a form suitable for further processing. Finally, the pulse driving approach also enables the implementation of randomized TX pulse phases (e.g., by use of an analog random generator or the like), with several positive effects from for example electromagnetic compatibility (EMC) and noise perspective, which were not applicable to the conventional techniques. For instance, the EM radiation that the transmitting coil may create to neighbouring circuits may be reduced.

To summarize the above, the present disclosure generally focuses on and describes in detail the following elements. First, there is an inductive sensor, which may be similar to the one conventionally used. Second, there is also described an ASIC that is coupled to the transmitting coil and the receiving coils such that it controls the current provided to the transmitting coil and processes the current output by the receiving coils. The ASIC itself may comprise, among others, an SRR concept based input gain stage which allows operation with very low RX signals, which is one of the side effects of the sensor miniaturization, but this comes without significant complexity on the amplifier, simply because it is reused many times for amplifying the same input signal (i.e., the SRR concept). It is to be noted that even if the function of this block may be considered to some extent identical to a classical comparator, the design of the last would be rather challenging, considering the low input signals and the short pulses, used to drive the transformer. Further, using the SRR also enables triggering the sensor with pulses, which in turn enables the technical objectives/effects discussed above. Considering short pulses as TX signal (e.g., ˜30 ns), the efficiency of the transformer (sensor) would still be high enough even with much smaller inductances of the coils. Together with that, the energy efficiency gets drastically increased and the design of the TX driver is greatly simplified. Moreover, the pulse driving approach also enables the implementation of randomized TX pulse phase (e.g., by use of an analog random generator), with many positive effects from EMC and noise perspective. In addition, the addition of asymmetry compensation attenuators/amplifiers at the input generally enables precise mechanical adjustment of the switching point of the system (sensor +ASIC), and implementation of mechanical hysteresis of the system, which may be considered beneficial for mitigating unwanted switching due to vibrations.

Techniques proposed in the present disclosure also bring several further advantages, which include (but are certainly not limited to): analog based design which is of low complexity and allows for relatively easy implementation; no need for any digital control logic for the basic switch functionality; possibility for mounting the sensor coils inside the IC package or even integrating them in the ASIC die; automatic safe-state entry by design when the SRR stage is present; high EMC robustness; low current consumption; low cost of goods sold (COGS); and minimized bill of material (BOM) of external components.

It may be worth noting that, the exemplary implementations using transmitter and receiver coils that may appear to have a specific wound, arrangement or placement as shown in the figures are merely provided for possible illustrative purposes, but are certainly not to be understood as a limitation of any kind. As can be understood and appreciated by the skilled person, any other suitable arrangement, implementation and/or application may be adopted.

It should be noted that the apparatus/device features described above correspond to respective method features that may however not be explicitly described, for reasons of conciseness. The disclosure of the present document is considered to extend also to such method features. In particular, the present disclosure is understood to also relate to methods of manufacturing and/or operating the circuits described above, and/or to providing and/or arranging respective elements of these circuits.

It is to be further noted that examples of embodiments of the disclosure are applicable to various applications or system configurations, depending on the underlying technical fields. In other words, the examples (such as the power tools) shown in the above-described figures, which are used as a basis for the above discussed examples, are only illustrative and do not limit the present disclosure in any way. That is, additional further existing and proposed new functionalities available in a corresponding operating environment may be used in connection with examples of embodiments of the present disclosure based on the principles defined.

It should also be noted that the disclosed example embodiments can be implemented in many ways using hardware and/or software configurations. For example, the disclosed embodiments may be implemented using dedicated hardware, dedicated software, and/or hardware in association with software executable thereon. The components and/or elements in the figures are examples only and do not limit the scope of use or functionality of any hardware, software in combination with hardware, firmware, embedded logic component, or a combination of two or more such components implementing particular embodiments of the present disclosure.

Finally, it should be noted that the description and drawings merely illustrate the principles of the proposed circuits and methods. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed method. Furthermore, all statements herein providing principles, aspects, and embodiments of the invention, as well as specific examples thereof, are intended to encompass equivalents thereof.

1. A circuitry for use with an inductive sensor, the inductive sensor comprising:
a transmitter coil and two back-to-back connected receiver coils for receiving signals induced by a magnetic field generated by the transmitter coil when excited; and
a movable conductive target for influencing the magnetic field,
wherein the circuitry is configured for generating a sequence of pulses for discontinuously exciting the transmitter coil.

2. The circuitry according to claim 1, wherein the generation of the sequence of pulses involves a randomized clocking scheme, so that the generated sequence of pulses have a variable duration between two consecutive pulses.

3. The circuitry according to claim 1, wherein the circuitry comprises a comparator stage configured for generating an output signal indicative of a position of the target relative to the receiver coils based on a differential output signal generated by the receiver coils.

4. The circuitry according to claim 3, wherein the comparator stage comprises a compensation stage coupled to the receiver coils for applying an asymmetric attenuation or amplification to a differential output signal generated by the receiver coils.

5. The circuitry according to claim 4, wherein the compensation stage is configured for nulling the differential output signal, so that a position of the target relative to the receiver coils can be inferred from information indicative of the applied attenuation or amplification.

6. The circuitry according to claim 4, wherein the compensation stage comprises two attenuators or amplifiers configured for individually attenuating or amplifying respective outputs of the receiver coils.

7. The circuitry according to claim 6, wherein the attenuators or amplifiers have variable gains for generating an output signal indicative of a position of the target relative to the receiver coils.

8. The circuitry according to claim 3, wherein the comparator stage comprises a super regenerative receiver, SRR, concept-based stage that is capable of self-quenching, such that an output of the SRR concept-based stage is gradually recoverable to a safe state in case of fault.

9. The circuitry according to claim 3, wherein the circuitry further comprises an integrator stage that is configured to be charged or discharged based on an output of the comparator stage.

10. The circuitry according to claim 9, wherein the circuitry further comprises a control stage coupled to the integrator stage for controlling at least one integration constant indicative of how fast an output of the integrator stage changes for each consecutive integration cycle.

11. The circuitry according to claim 10, wherein the control stage is configured such that, when the output of the comparator stage indicates a change of the position, the output of the comparator stage gets integrated with a smaller step in the integrator stage, than the case when the output of the comparator stage indicates no change of the position.

12. The circuitry according to claim 1, wherein the circuitry comprises both a compensation stage coupled to the receiver coils for attenuating or amplifying a differential output signal generated by the receiver coils, and a super regenerative receiver, SRR, concept-based stage coupled to the compensation stage that is capable of self-quenching.

13. The circuitry according to claim 1, wherein the circuitry is powered in synchronization with the sequence of pulses.

14. The circuity according to claim 3, wherein the comparator stage receives and processes signals from the receiver coils synchronously with the sequence of pulses.

15. The circuitry according to claim 1, wherein the circuitry is configured for determining short or long distance, one-way or two-way movement of the target, and/or configured for sensing a linear position or a rotational angle of the target.

16. The circuitry according to claim 1, wherein the circuitry and the inductive sensor are coupled in series.

17. A method of operating a circuitry for use with an inductive sensor, the inductive sensor comprising:
a transmitter coil and two back-to-back connected receiver coils for receiving signals induced by a magnetic field generated by the transmitter coil when excited; and
a movable conductive target for influencing the magnetic field,
wherein the method comprises:
generating a sequence of pulses for discontinuously exciting the transmitter coil.
